(19) United States
(12) Patent Application Publication
(10) Pub. No.: US 2008/0218188 A1
(43) Pub. Date: Sep. 11, 2008

(54) JIG FOR PRINTED SUBSTRATE INSPECTION AND PRINTED SUBSTRATE INSPECTION APPARATUS

(75) Inventors: Koji ARAI, Nagano-shi (JP); Hideyuki Wakabayashi, Nagano-shi (JP); Atsushi Maruyama, Nagano-shi (JP); Tomofumi Kikuchi, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-shi (JP)

(21) Appl. No.: 12/044,593

(22) Filed: Mar. 7, 2008

(30) Foreign Application Priority Data
Mar. 8, 2007 (JP) 2007-058427

(51) Int. Cl. G01R 31/02

(52) U.S. Cl. 324/755

(57) ABSTRACT

In a jig for inspection for inspecting a printed substrate in which a wiring part is formed on at least one surface, the jig comprises a base part which has a surface area larger than a surface area of at least the printed substrate targeted for inspection and is arranged as opposed to one surface of the printed substrate, and plural probe pins aligned and arranged at a predetermined distance mutually, any top end of the probe pin abutting on the wiring part of the printed substrate.

This application claims priority to Japanese Patent Application No. 2007-058427, filed Mar. 8, 2007, in the Japanese Patent Office. The priority application is incorporated by reference in its entirety.

### TECHNICAL FIELD

The present disclosure relates to a jig for inspection used by abutting on a printed substrate in order to inspect a short circuit or a break in wiring of the printed substrate and an inspection apparatus using this jig.

### RELATED ART

A printed substrate for mounting a semiconductor element includes a printed substrate such as a BGA (Ball Grid Array) in which wiring patterns are formed on both surfaces of a substrate.

In this BGA, a semiconductor element is mounted on one surface and a bond finger connected to the semiconductor element by wire bonding is disposed in the periphery of a mounting position of the semiconductor element. Also, a ball pad for connecting an external connection terminal is disposed on the other surface of the BGA. A via for electrically connecting the bond finger to the ball pad is formed in a thickness direction of the BGA.

In the printed substrate, in which wiring parts such as the ball pad or the bond finger made of metal are disposed on both surfaces as described above and the mutual wiring parts of each of the surfaces are electrically connected, it is essential to make a short-circuit check or a continuity check of the wiring parts of both surfaces.

Therefore, in the case of make a short-circuit check or a continuity check of the wiring parts in the printed substrate, there is a printed substrate inspection apparatus in which the check is made by abutting plural probe pins on the wiring parts (for example, see Patent Reference 1, Patent Reference 2 and Patent Reference 3).

[Patent Reference 1] Japanese Patent Application Publication No. 9-178774

[Patent Reference 2] Japanese Utility Model Application Publication No. 6-30780

[Patent Reference 3] Japanese Patent Application Publication No. 2000-171512

As described in each of the above Patent References, it was necessary to arrange a probe pin in the printed substrate inspection apparatus according to a pattern shape of a wiring part of a printed substrate in order to make its check completely.

As a result of this, a jig in which arrangement of a probe pin is changed every printed substrate must be adopted in the printed substrate inspection apparatus and high cost is required in order to manufacture the jig each time. Also, management of jigs is also complicated and takes much time and effort when a kind of the printed substrate is large.

Further, in recent years, a pitch of a bond finger in the BGA as described above becomes narrower (about 50 μm to 100 μm) and too much time and effort are taken in order to develop a special jig, so that a method for making a continuity check by pressing conductive rubber on the whole surface of a printed substrate is also adopted. However, in such a method, the continuity check can be made, but a short-circuit check cannot be made. Therefore, its check cannot be made completely.

### SUMMARY

Exemplary embodiments of the present invention provide a jig for printed substrate inspection in which it is unnecessary to be specially designed every printed substrate and also a complete inspection can be made, and a printed substrate inspection apparatus using this jig.

That is, according to a jig for printed substrate inspection according to the invention, in a jig for inspection for inspecting a printed substrate in which a wiring part is formed on at least one surface, the jig is characterized by comprising a base part which has a surface area larger than a surface area of at least the printed substrate targeted for inspection and is arranged as opposed to one surface of the printed substrate, and plural probe pins aligned and arranged at a predetermined distance mutually, any top end of the probe pin abutting on a wiring part of the printed substrate.

By adopting this configuration, the printed substrate can be inspected regardless of a kind of the printed substrate, so that cost necessary to manufacture a special jig, time and effort of management of the special jig, etc. can be reduced.

Also, it may be wherein an insertion hole into which each of the probe pins is inserted is formed in the base part, and each of the probe pins is inserted into the insertion hole movably with respect to the base part so as to descend in a direction of the top end under pin's own weight and a retaining mechanism for being retained so as not to come out of the insertion hole at the time of a descent is disposed.

According to this configuration, the probe pin descends under pin's own weight, so that contact between the probe pin and the wiring part of the printed substrate is ensured.

Also, it may be wherein an urging member for urging in a direction of the top end is disposed in each of the probe pins.

According to this configuration, contact between the probe pin and the wiring part of the printed substrate can be ensured further.

Further, it may be wherein the back end of each of the probe pins is disposed as a terminal part to which electrical wiring for making electrical connection to an external device is connected.

Further, it may be wherein an inner wall surface of an insertion hole of the base part is formed by a conductive substance, and a terminal part to which electrical wiring which is electrically connected to the inner wall surface of the insertion hole and makes electrical connection to an external device is connected is disposed on a surface of the base part.

According to this configuration, it is unnecessary to directly connect the electrical wiring to the probe pin, so that wiring to the external device can be performed surely even when a distance between the mutual probe pins is narrow.

Also, it may be wherein the base part is formed in a multilayer structure of at least two layers or more, and each of the probe pins is arranged inside an insertion hole formed in the base part, and plural terminal parts to which electrical wiring for making electrical connection to an external device is connected are formed on a surface of the highest layer of the base part, and a wiring pattern and a via are formed in the base part so that each of the probe pins is electrically connected to each of the terminal parts in a one-to-one correspondence.

According to this configuration, the terminal part for connection can be set in any position of the base part even when the electrical wiring is not directly connected to the probe pin. As a result of this, connection of the electrical wiring can be made easily by widening a distance between the terminal parts for connecting the electrical wiring to the external device even when the probe pins must be arranged at a narrow pitch.

Further, it may be wherein an alignment distance between the terminal parts of the highest layer is disposed so as to become wider than an alignment distance between the probe pins.

According to this configuration, connection of the electrical wiring to the terminal part can be made easily even when the probe pins must be arranged at a narrow pitch.

Also, it may be wherein a cover in which an opening part opened along the outer edge of a printed substrate targeted for inspection is formed is detachably disposed on a surface of the base part located in the top end side of the probe pin.

By adopting this configuration, the probe pin arranged in a place which does not abut on the wiring part of the printed substrate essentially can be prevented from accidentally abutting on the wiring part of the printed substrate.

According to a printed substrate inspection apparatus according to the invention, in an inspection apparatus for inspecting a printed substrate in which wiring parts are formed on both surfaces and the mutual wiring parts of both surfaces are electrically connected, the apparatus is characterized by comprising a first jig for printed substrate inspection having a configuration as described in above, a second jig for printed substrate inspection which is arranged as opposed to the other surface of the printed substrate and has plural probes abutting on the wiring part formed on the other surface of the printed substrate, and a control part which is connected to each of the probe pins of the first jig for printed substrate inspection and each of the probes of the second jig for printed substrate inspection through electrical wiring and performs control so as to make a short-circuit check and a continuity check between each of the probe pins and each of the probes.

By adopting this configuration, the printed substrate can be inspected regardless of a kind of the printed substrate, so that cost necessary to manufacture a special jig, time and effort of management of the special jig, etc. can be reduced and further, the probe pins and the probes can surely be brought into contact with each of the wiring parts, so that a complete check including the short-circuit check can be made.

In addition, it may be wherein the second jig for printed substrate inspection is a jig for printed substrate inspection having a configuration as described above.

According to a jig for printed substrate inspection according to the invention, even for a printed substrate with a different pattern of a wiring part, it can be used in common and contributes to cost reduction and also, time and effort of management can be reduced.

Also, according to a printed substrate inspection apparatus according to the invention, even for a printed substrate with a different pattern of a wiring part, it can be used in common, and cost reduction and time and effort of management can be reduced and also, a complete check can be made.

Other features and advantages may be apparent from the following detailed description, the accompanying drawings and the claims.

### BRIEF DESCRIPTION OF THE DRAWINGS

FIG. 1 is a plan view of a jig for printed substrate inspection of a first embodiment according to the invention.

FIG. 2 is a side view showing a state of arranging the jig for printed substrate inspection of the first embodiment in a printed substrate.

FIG. 3 is a side view of the jig for printed substrate inspection in a state of attaching a cover.

FIGS. 4A to 4C are a plan view, a side view and a bottom view of a jig for printed substrate inspection of a second embodiment.

FIG. 5 is a sectional view of a base part showing a structure of attachment of a probe pin to the base part.

FIG. 6 is a sectional view of a base part describing an example of attaching a spring to a probe pin.

FIG. 7 is a sectional view of a base part showing an example of disposing a spring inside a probe pin.

FIG. 8 is a sectional view of a base part showing an example of disposing a spring between a probe pin and a fixed member.

FIG. 9 is a sectional view of a base part showing an example of an integral structure of a spring and a probe pin.

FIG. 10 is a sectional view of a base part showing an example of disposing an elastic member between a probe pin and the base part.

FIG. 11 is a sectional view of a base part showing another example in attachment of the elastic member of FIG. 10.

FIG. 12 is a sectional view of a base part showing other example in attachment of the elastic member of FIG. 10.

FIG. 13 is a sectional view of a base part showing one example of a retaining structure of a probe pin.

FIG. 14 is a sectional view of a base part showing one example of a retaining structure of a probe pin.

FIG. 15 is a block diagram showing an outline configuration of a printed substrate inspection apparatus according to the invention.

FIG. 16 is a side view of the printed substrate inspection apparatus.

### DETAILED DESCRIPTION

Preferred embodiments of the invention will hereinafter be described in detail based on the accompanying drawings.

### FIRST EMBODIMENT

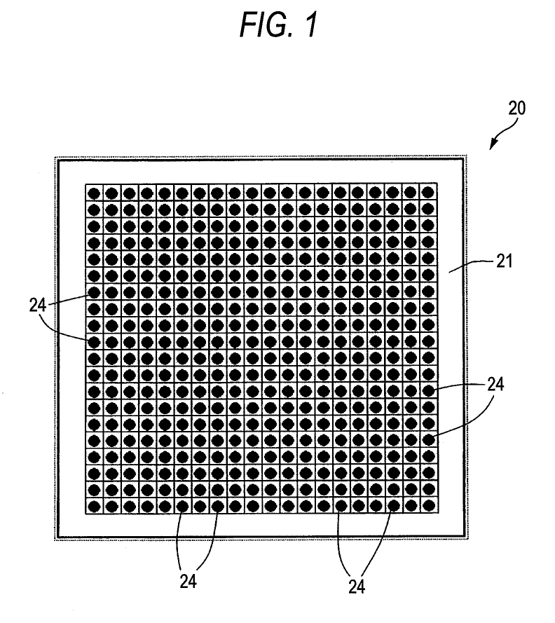

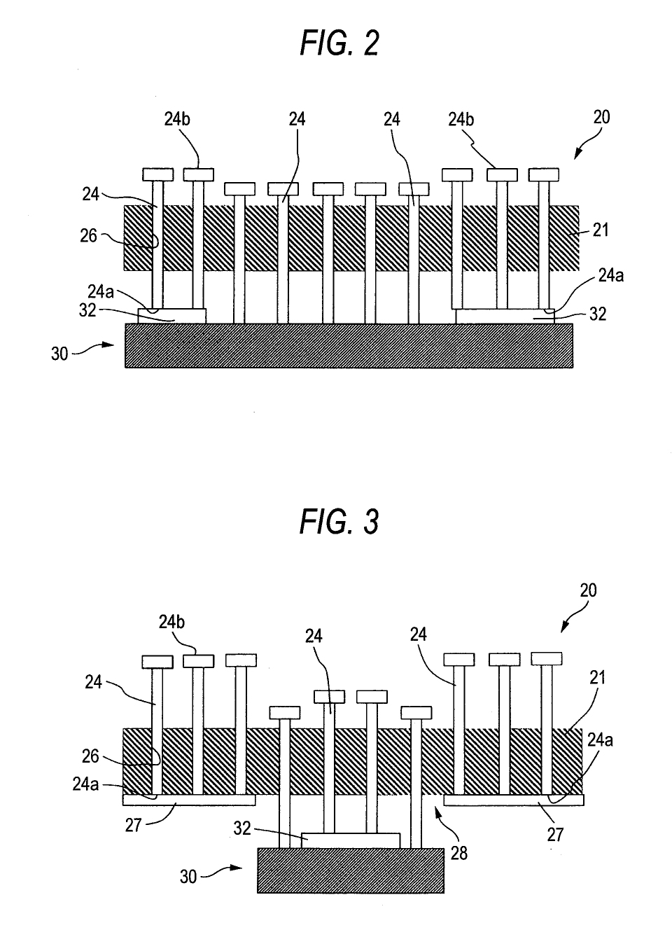

FIG. 1 shows a plan view of a jig for print inspection of the present embodiment, and FIG. 2 shows a side view at the time of arranging the jig of FIG. 1 in a printed substrate. In addition, a solder resist or a ball pad of a printed substrate 30 is omitted in FIG. 2.

A jig 20 for printed substrate inspection of the embodiment comprises a base part 21 formed by an insulating member such as a synthetic resin having a predetermined thickness of a quadrilateral shape in the case of being viewed from the plane, and plural probe pins 24 formed by a conductive member. A substrate in which insertion holes are formed in a silicon substrate and an insulating film such as an oxide film (SiO₂) is formed on the whole surface including inner walls of the insertion holes may be used as the base part 21.

Also, the printed substrate 30 targeted for inspection shall be a BGA. The probe pins 24 abut on bond fingers 32 (wiring patterns) of the printed substrate 30.

Insertion holes 26 extending through both surfaces in order to insert the probe pins 24 are aligned and formed in the whole surface of the base part 21 at a predetermined distance. A distance between the mutual insertion holes 26 is disposed so as to become narrower than a pitch of the bond fingers 32 of the printed substrate 30.

Also, in the printed substrate 30 targeted for inspection in the embodiment, the pitch of the bond fingers 32 becomes narrower (about 100 μm to 50 μm). Therefore, the distance between the mutual insertion holes 26 is formed so as to become smaller than at least 50 μm.

Also, places of the insertion holes 26 are arranged in a grid shape irrespective of arrangement of the bond fingers 32 of the printed substrate 30. Therefore, each of the probe pins 24 inserted into the plural insertion holes 26 includes probe pins abutting on the bond fingers 32 and probe pins abutting on regions other than the bond fingers 32. The jig for printed substrate inspection of the present application greatly differs from a related-art jig for printed substrate inspection in this respect.

A surface area of the base part 21 is formed so as to become larger than a surface area of at least the printed substrate 30 targeted for inspection. It is preferable to have a surface area in which surfaces of all the printed substrates 30 are covered in the case of arranging plural printed substrates 30 so that the plural printed substrates 30 can be inspected at once.

The probe pin 24 is a member formed in a columnar shape extending straight in order to make electrical connection by abutting on a wiring part such as the bond finger 32 of the printed substrate 30 such as a BGA. A probe pin in which plating such as rhodium plating, nickel plating or gold plating is given to beryllium copper can be used. In the embodiment, a length of the probe pin 24 is formed so as to become longer than a thickness of the base part 21.

The top end 24a of the probe pin 24 is formed so as not to be sharp for preventing damage to a wiring part abutting. Then, the back end 24b of the probe pin 24 is disposed as a terminal part for connecting electrical wiring to an external device (not shown, a computer etc. as described in a third embodiment). Also, the back end 24b of the probe pin 24 is formed in a diameter larger than a diameter of the insertion hole 26 as a retaining part abutting on an upper surface of the base part 21 so as not to fall out of the insertion hole 26 at the time of a descent.

Also, a diameter of the probe pin 24 is formed in a diameter slightly smaller than the diameter of the insertion hole 26. The probe pin 24 is inserted slidably with respect to the insertion hole 26 of the base part 21 so as to descend inside the insertion hole 26 under pin's own weight. Thus, the probe pin 24 can surely make contact with the wiring part under pin's own weight.

Subsequently, FIG. 3 shows a configuration in which a cover 27 is disposed on the base part 21.

The cover 27 formed by an insulator such as a synthetic resin is disposed on a lower surface of the base part 21. The cover 27 has an opening part 28 capable of accommodating the printed substrate 30 targeted for inspection. Only the probe pins 24 positioned inside the opening part 28 descend and abut on the printed substrate 30.

By disposing the cover 27, the probe pins 24 arranged in a place which is positioned in the vicinity of the outer edge of the printed substrate 30 and does not abut on a wiring part of the printed substrate 30 essentially can be prevented from accidentally abutting on the wiring part of the printed substrate 30. Also, the cover 27 in which opening parts 28 are respectively formed in positions corresponding to each of the printed substrates 30 is disposed when plural printed substrates 30 are inspected for one jig 20 for printed substrate inspection.

The cover 27 is disposed detachably from the base part 21. As a result of this, plural kinds of covers in which opening parts 28 are formed according to sizes of printed substrates 30 targeted for inspection are prepared and the cover 27 is replaced every time the printed substrate 30 targeted for inspection is changed.

### SECOND EMBODIMENT

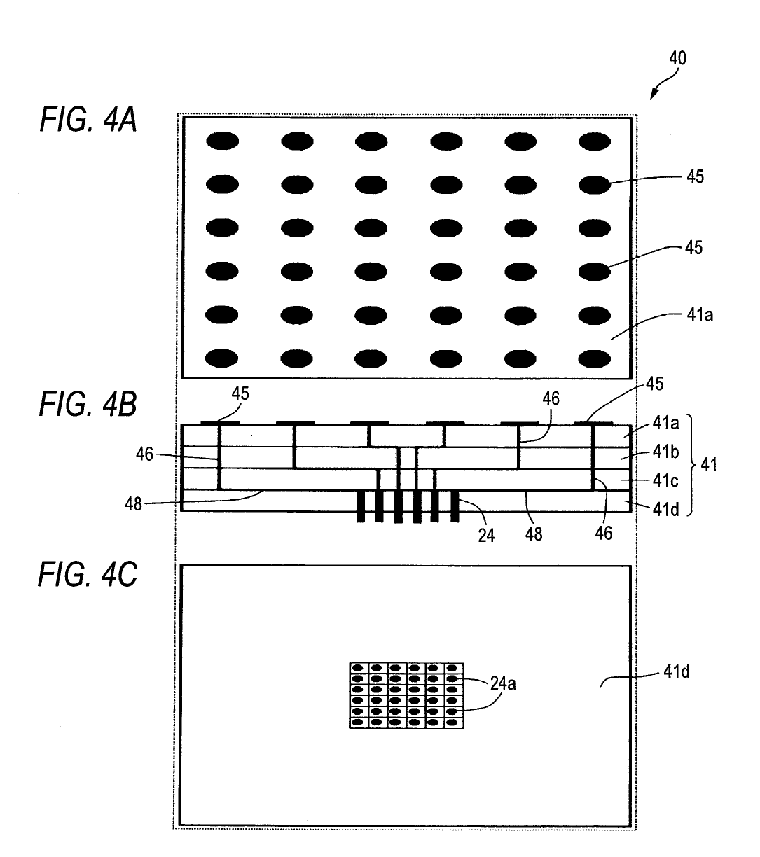

Next, a second embodiment of a jig for printed substrate inspection will be described based on FIGS. 4A to 4C. FIG. 4A is a plan view of the jig for printed substrate inspection of the present embodiment, and FIG. 4B is a sectional view from a side surface of the jig for printed substrate inspection, and FIG. 4C is a bottom view of the jig for printed substrate inspection. In addition, description may be omitted by assigning the same numerals to the same components as those of the embodiment described above.

In a jig 40 for printed substrate inspection of the embodiment, terminal parts 45 to which electrical wirings for making electrical connections to probe pins 24 are connected are disposed at a wide distance.

A base part 41 is formed in a hierarchical structure similar to a multilayer printed substrate, and is herein formed in a four-layer structure as one example. The base part 41 is formed by a synthetic resin which is an insulator.

The probe pin 24 is disposed inside a low layer part 41d formed in the lowest part. Also, electrical wiring (not shown) connected to an external device is connected to the terminal part 45 disposed on an upper surface of a high layer part 41a formed on the highest part of the base part 41. Any of the plural terminal parts 45 of the high layer part 41a is electrically connected to any of the plural probe pins 24 of the low layer part 41d in a one-to-one correspondence. The electrical connection between the terminal part 45 and the probe pin 24 is made through a via 46 and a wiring pattern 48. The via 46 is formed along a thickness direction so as to extend through each of the hierarchies of the base part 41, and the wiring pattern 48 is formed on a surface of each of the hierarchies and makes connection between each of the mutual vias 46 or the via 46 and an insertion hole 50.

In addition, the insertion hole 50 is not limited to formation in only the low layer part 41d, and may be formed by extending through plural hierarchies (for example, the low layer part 41d and a middle layer part 41c).

A distance between the plural probe pins 24 is disposed so as to become narrower than a pitch of bond fingers 32 of a printed substrate 30, but a distance between the terminal parts 45 is disposed so as to become wider than a pitch of the probe pins 24.

When the pitch of the bond fingers 32 of the printed substrate 30 targeted for inspection becomes narrower, a mutual distance must be narrowed as described above in the side of the top end 24a of each of the probe pins 24, but in the embodiment, electrical wiring to each of the probe pins 24 is connected to the terminal part 45 in which the mutual distance is sufficiently ensured, so that connection can be made easily even for relatively thick electrical wiring.

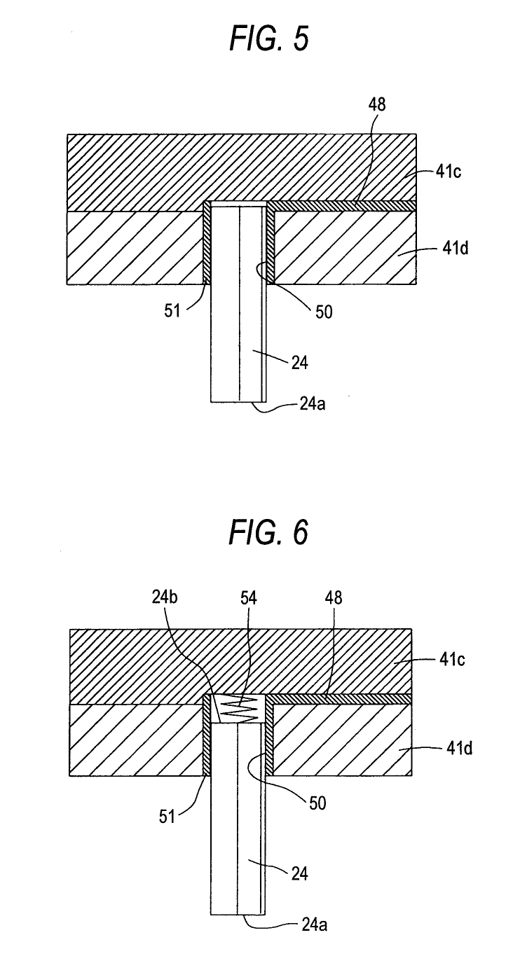

Subsequently, FIG. 5 shows one example of an attachment structure of a probe pin and the probe pin in the embodiment.

The insertion hole 50 into which a probe pin 24 is inserted is formed in a low layer part 41d of a base part 41. The insertion hole 50 is formed so as to extend through a thickness direction of the low layer part 41d, but a middle layer part 41c is placed on an upper surface of the low layer part 41d, so that an upper surface of the insertion hole 50 is blocked by a lower surface of the middle layer part 41c.

A conductive substance 51 such as copper is formed on an inner wall surface of the insertion hole 50 by copper plating etc. As a result of this, the probe pin 24 slides inside the insertion hole 50 and thereby, electrical connection between the probe pin 24 and the inner wall surface of the insertion hole 50 is made.

Also, a wiring pattern 48 connected to the inner wall surface of the insertion hole 50 is formed on the upper surface of the low layer part 41d. The wiring pattern can be formed by, for example, performing etching processing of copper foil like a normal printed substrate. The wiring pattern 48 is connected to a via 46 formed from the middle layer part 41c to a high layer part 41a. In addition, a via 46 extending through the portion from the low layer part 41d to the middle layer part 41c or 41b or extending through the portion from the low layer part 41d to the high layer part 41a may be formed and the probe pin 24 may be disposed so as to be directly connected to this via 46.

The terminal part 45 made of a wiring pattern etc. is formed in an opening part of the via 46 in an upper surface of the high layer part 41a.

Also, when force of contact between the probe pin 24 and a bond finger 32 is weak in the embodiment, an urging member for urging the probe pin 24 in a direction of the top end could be disposed in order to surely bring the probe pin 24 into contact with the bond finger 32.

Examples of disposing the urging member are shown in FIGS. 6 to 12. In addition, description may be omitted by assigning the same numerals to the same components as the components shown in FIG. 5.

First, an example shown in FIG. 6 will be described.

A spring 54 acting as urging member is attached between a lower surface of a middle layer part 41c and the back end 24b of a probe pin 24 in this example so as to join the probe pin 24 to the middle layer part 41c of a base part 41.

Since the probe pin 24 is arranged slidably inside an insertion hole 50, the spring 54 has a role of attaching the probe pin 24 to the middle layer part 41c and also has a retaining function. Here, the probe pin 24 is electrically connected to an inner wall surface of the insertion hole 50.

Then, when the top end 24a of the probe pin 24 abuts on a bond finger 32, the probe pin 24 is pushed upward and the spring 54 is compressed. Then, urging force of stretching the compressed spring 54 acts on the probe pin 24 and the probe pin 24 is pressurized and can surely make contact with the bond finger 32.

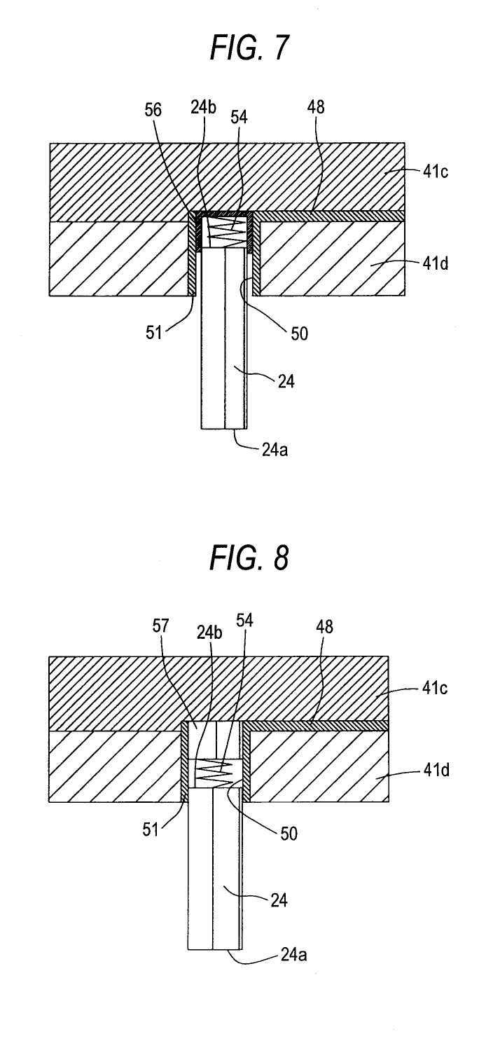

A configuration of building a spring 54 into the side of the back end 24b of a probe pin 24 is adopted in an example shown in FIG. 7.

Here, a case part 56 with a diameter larger than that of a body of the probe pin 24 is disposed in the side of the back end 24b of the probe pin 24, and the spring 54 is attached between the back end 24b of the probe pin 24 and an upper surface of the inside of the case part 56. On the other hand, the case part 56 is constructed so as to be fixed to an inner wall surface of an insertion hole 50. Also, the case part 56 and the spring 54 have conductivity. The probe pin 24 is electrically connected to the inner wall surface of the insertion hole 50 through the case part 56 and the spring 54.

Therefore, the case part 56 of the probe pin 24 is disposed as a retaining part from the insertion hole 50. Then, when the top end 24a of the probe pin 24 makes contact with a bond finger 32, the spring 54 is compressed. Urging force of stretching the compressed spring 54 acts on the probe pin 24 and the probe pin 24 can surely make contact with the bond finger 32.

In FIG. 8, a spring 54 is attached to the side of the back end 24b so as to expose the spring 54 rather than accommodating the spring 54 in a probe pin 24.

Also, a fixed member 57 is connected to the back end 24b of the probe pin 24 through the spring 54. A shape of the fixed member 57 may be any shape, but it is necessary to have conductivity while being disposed so as to be able to be fixed inside an insertion hole 50. Also, the spring 54 has conductivity. The probe pin 24 is electrically connected to an inner wall surface of the insertion hole 50 through the spring 54 and the fixed member 57.

In this configuration, the fixed member 57 has a retaining function and also when the top end 24a makes contact with a bond finger 32, the spring 54 is compressed with the fixed member 57. Then, urging force of stretching the compressed spring 54 acts on the probe pin 24 and the probe pin 24 can surely make contact with the bond finger 32.

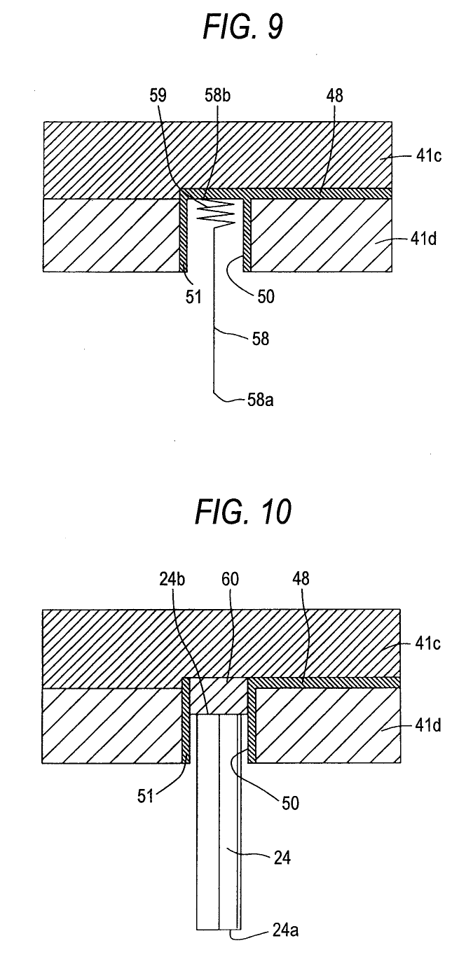

FIG. 9 shows a configuration of integrating a probe pin with a spring.

This probe pin 58 is formed in a bar shape extending substantially straight in the side of the top end 58a so as to abut on a bond finger 32 in the top end 58a and is formed as a spring part 59 wound in a coil shape so that the side of the back end 58b has a role of urging member. The back end 58b of the probe pin 58 is attached to a middle layer part 41c. Also, a wiring pattern 48 is extended to a region of the middle layer part 41c to which the back end 58b of the probe pin 58 is attached, and the wiring pattern 48 is electrically connected to the probe pin 58.

In this example, the probe pin 58 itself has a retaining function by being directly attached to a base part 41 and also when the top end 58a makes contact with a bond finger 32, the spring part 59 is compressed with the middle layer part 41c. Then, urging force of stretching the compressed spring part 59 acts on the probe pin 58 and the probe pin 58 can surely make contact with the bond finger 32.

Examples of adopting conductive elastic members as other structures of the urging member are shown in FIGS. 10 to 12.

This elastic member 60 is formed by conductive rubber etc. having conductivity, and is disposed so that electrical connection between a probe pin 24 and an inner wall surface of an insertion hole 50 can be made. Also, the elastic member 60 has a function as a retaining part from the insertion hole 50 by being formed in a columnar shape with substantially the same diameter as an inside diameter of the insertion hole 50.

The elastic member 60 in FIG. 10 is arranged between a middle layer part 41c and the back end 24b of a probe pin 24, and when the top end 24a of the probe pin 24 makes contact with a bond finger 32, the elastic member 60 is compressed between the middle layer part 41c and the back end 24b. Then, urging force of stretching the compressed elastic member 60 acts on the probe pin 24 and the probe pin 24 can surely make contact with the bond finger 32.

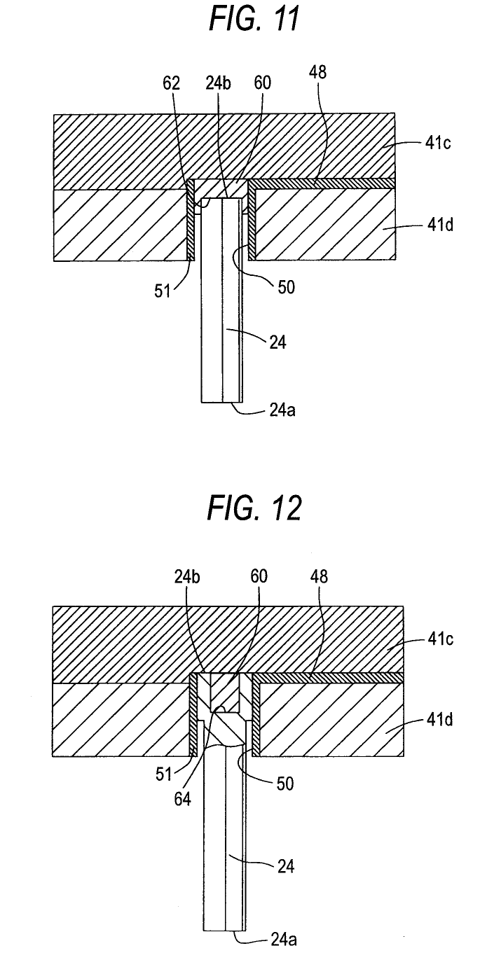

FIG. 11 is an example in which the back end 24b of a probe pin 24 is inserted into an insertion hole 62 formed in a lower surface of an elastic member 60 and is fixed to the probe pin 24.

FIG. 12 shows an example in which an elastic member 60 is inserted into an insertion hole 64 formed in an end face of the back end 24b of a probe pin 24 and is fixed.

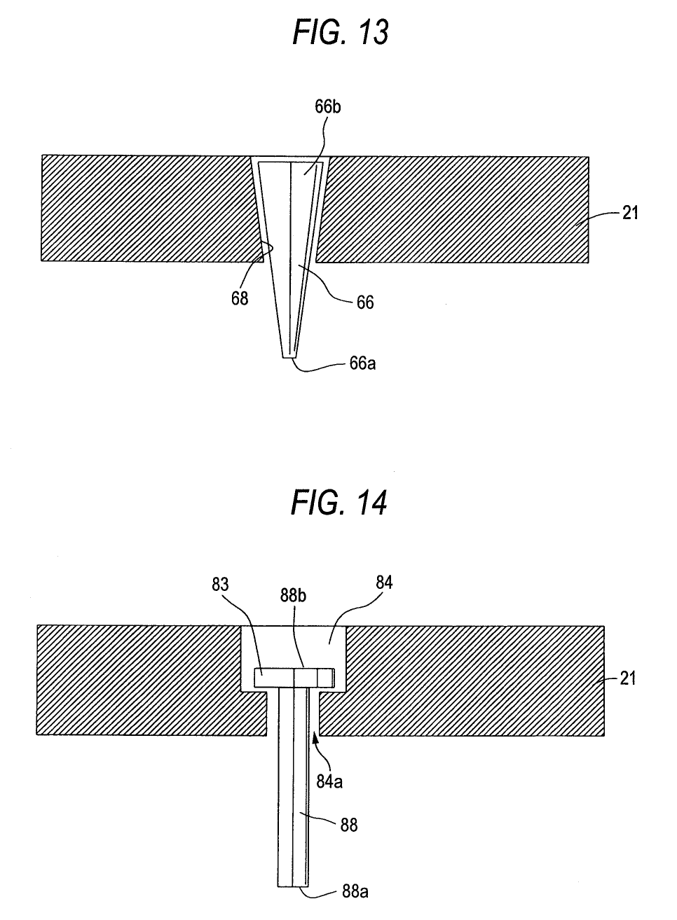

In addition, other examples of a retaining mechanism capable of being adopted in both of the first embodiment and the second embodiment described above are shown in FIGS. 13 and 14.

In the example shown in FIG. 13, a probe pin 66 is formed so that a diameter of the probe pin becomes smaller gradually toward the side of the top end 66a. Then, an insertion hole 68 of a base part 21 into which the probe pin 66 is inserted is also formed so that a diameter of the insertion hole becomes smaller gradually toward a lower portion. A conductive substance such as copper may be formed on an inner wall surface of the insertion hole 68 by copper plating etc.

By being formed thus, even when the probe pin 66 descends inside the insertion hole 68 under pin's own weight, the back end 66b of a large diameter of the probe pin 66 abuts on the inner wall surface of the insertion hole 68 and the probe pin 66 is disposed so as not to move to the portion lower from the abutting place.

Also, in FIG. 14, a large diameter part 83 larger than a diameter of the top end 88a is disposed in a middle part or the back end 88b of a probe pin 88 and an opening part 84a of a lower surface of an insertion hole 84 of a base part 21 is formed in a diameter of the extent to which the large diameter part 83 cannot pass. A conductive substance such as copper may be formed on an inner wall surface of the insertion hole 84 by copper plating etc.

By being formed thus, the probe pin 88 descending under pin's own weight can be retained.

### THIRD EMBODIMENT

Next, a printed substrate inspection apparatus using the jig for printed substrate inspection mentioned above will be described.

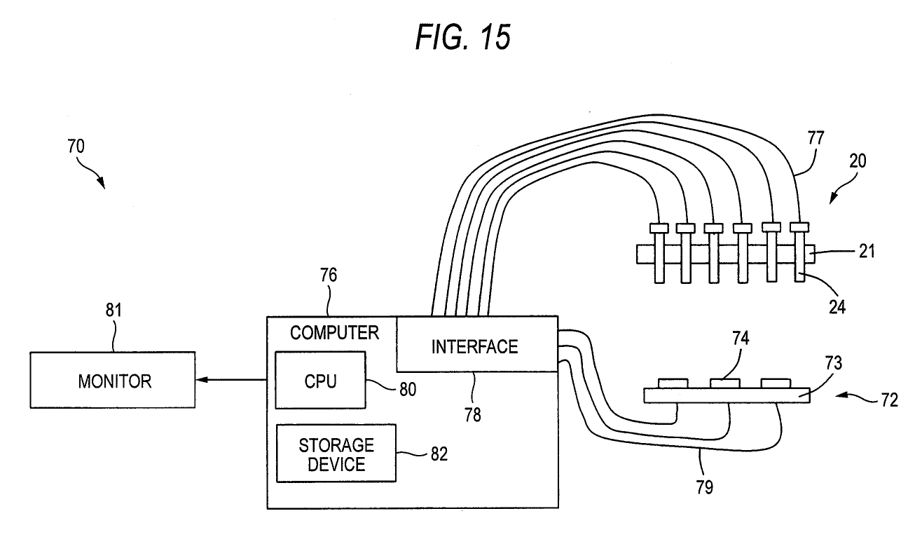

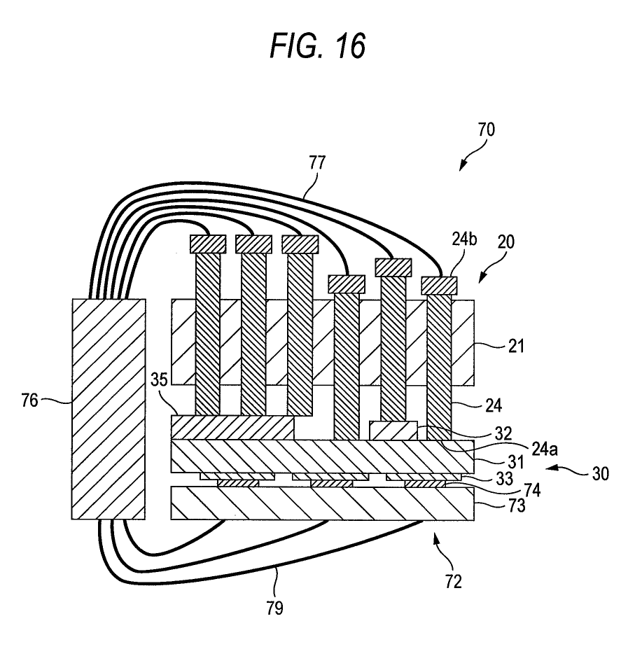

FIG. 15 is a block diagram describing an outline configuration of the printed substrate inspection apparatus, and FIG. 16 is a side view showing a wiring structure of the printed substrate inspection apparatus. In addition, description may be omitted by assigning the same numerals to the same components as those of the embodiments described above.

Here, a printed substrate 30 targeted for inspection is a BGA and wiring parts are formed on both surfaces of a substrate 31. Therefore, two jigs for printed substrate inspection are required.

A printed substrate inspection apparatus 70 comprises a jig 20 for printed substrate inspection arranged in the upper surface side of the printed substrate 30 targeted for inspection, a jig 72 for printed substrate inspection arranged in the lower surface side of the printed substrate 30 targeted for inspection, and a control part 76 for connecting both the jigs 20, 72 for printed substrate inspection and making a continuity check and a short-circuit check.

Here, the jig 20 for printed substrate inspection described in the first embodiment is arranged in the upper surface side of the printed substrate 30, and electrical wirings 77 for making connection to the control part 76 are connected to the back ends 24b of each of the probe pins 24.

Also, a jig for printed substrate inspection of a configuration different from that of the jig for printed substrate inspection described above is arranged and used in the lower surface side of the printed substrate 30.

A normal computer can be used as the control part 76.

The computer 76 has an interface 78 for connecting both the jigs 20, 72 for printed substrate inspection and sending and receiving a signal, a CPU 80 for controlling the whole action of the computer 76, and a storage device 82 made of ROM or a hard disk in which a program for printed substrate inspection is stored. Also, a monitor 81 for displaying an inspection result etc. is connected to the computer 76.

In the printed substrate 30, a semiconductor element is mounted on an upper surface of the substrate 31 and bond fingers 32 are formed so as to surround the outer periphery of a mounting position of the semiconductor element. Numeral 35 located on the upper surface of the substrate 31 is a solder resist.

Also, ball pads 33 are formed on a lower surface of the substrate 31 of the printed substrate 30. The ball pads 33 are terminals disposed for external connection, and the number of ball pads 33 is smaller than the number of bond fingers 32 and also the ball pads 33 are disposed at a wider pitch.

The jig 72 for printed substrate inspection arranged in the lower surface side of the printed substrate 30 comprises a base part 73 which has a quadrilateral shape in the case of being viewed from the plane and is formed so as to become larger than a surface area of at least the printed substrate 30 targeted for inspection, and probes 74 electrically connected to the ball pads 33. In the embodiment, the probes 74 are formed in positions corresponding to the ball pads 33.

The probe 74 is an electrode formed in substantially a flat plate shape on an upper surface of the base part 73, and is formed smaller than a surface area of the ball pad 33. The probes 74 are connected to electrical wirings 79 connected to an external device through the base part 73.

The program for printed substrate inspection stored inside the storage device 82 of the computer 76 is read out by the CPU 80 and the CPU 80 controls each configuration and thereby, the printed substrate 30 can be inspected.

Further, a normal state in the case of previously connecting the jigs 20, 72 for printed substrate inspection to the printed substrate 30 targeted for inspection and passing a current for inspection through the printed substrate 30 is stored in the storage device 82.

The CPU 80 reading out the program for printed substrate inspection performs control so as to pass a current for inspection through the probe pins 24 of the jig 20 for printed substrate inspection or the probes 74 of the jig 72 for printed substrate inspection via the electrical wirings 77 or the electrical wirings 79. Then, the CPU 80 checks whether there is continuity between any of the probe pin 24 and the probe 74, and compares its result with the normal state stored in the storage device 82. Consequently, checks of continuity between the bond fingers 32 and the ball pads 33 are made accurately.

Also, the CPU 80 makes checks of a short circuit in the mutual probe pins 24 and checks of a short circuit in the mutual probes 74. The short-circuit checks are made by checking the presence or absence of continuity between the mutual probe pins 24 and between the mutual probes 74. In a manner similar to the continuity checks in the short-circuit checks, its result is compared with the normal state stored in the storage device 82. Consequently, checks of a short circuit in the mutual bond fingers 32 and checks of a short circuit in the mutual ball pads 33 are made accurately.

In addition, in the printed substrate inspection apparatus 70 of the embodiment, the probes 74 of the jig 72 for printed substrate inspection arranged in the lower surface side of the printed substrate 30 have been formed in the flat plate shape. However, the invention is not limited to this configuration, and the jig for printed substrate inspection according to the first or second embodiment described above may be used as the jig for printed substrate inspection arranged in the lower surface side of the printed substrate 30.

The invention has variously been described above by giving the preferred embodiments, but the invention is not limited to the embodiments, and many modifications can naturally be made without departing from the spirit of the invention.

What is claimed is:

1. A jig for inspecting a printed substrate in which a wiring part is formed on at least one surface, comprising:
a base part which is arranged as opposed to said one surface of the printed substrate and has a surface area larger than a surface area of at least the printed substrate targeted for inspection; and
a plurality of probe pins aligned and arranged at a predetermined distance mutually so that a top end of any probe pin abuts on the wiring part of the printed substrate.

2. A jig as claimed in claim 1, wherein the base part has a plurality of insertion holes, into which the respective probe pins are inserted, and wherein each of the probe pins has a retaining mechanism for being retained so as not to come out of the insertion hole.

3. A jig as claimed in claim 1, further comprising:
an urging member for urging the probe pin in a direction of the top end of each of the probe pins.

4. A jig as claimed in claim 1, wherein a back end of each of the probe pins serves as a terminal part to which electrical wiring for making electrical connection to an external device is connected.

5. A jig as claimed in claim 1,
wherein the base part has a plurality of insertion holes, into which the respective probe pins are inserted, and a conductive substance is formed on an inner wall surface of each of the insertion holes of the base part, and
wherein a terminal part, which is electrically connected to the inner wall surface of said insertion hole, and to which electrical wiring for making electrical connection to an external device is connected, is disposed on a surface of the base part.

6. A jig as claimed in claim 1,
wherein the base part is formed in a multilayer structure of at least two layers or more, the base part has a plurality of insertion holes formed in at least lowest layer, and the respective probe pins are inserted in the respective insertion holes, and
wherein a plurality of terminal parts to which electrical wiring for making electrical connection to an external device is connected are formed on a surface of the highest layer of the base part, and each of the probe pins is electrically connected to each of the terminal parts in a one-to-one correspondence through a wiring pattern and a via formed in the base part.

7. A jig as claimed in claim 6, wherein an alignment distance between the terminal parts of the highest layer is disposed so as to become wider than an alignment distance between the probe pins.

8. A jig as claimed in claim 1, further comprising:
a cover which has an opening part opened along an outer edge of the printed substrate targeted for inspection and is attached to a surface of the base part which is opposed to said one surface of the printed substrate.

9. A jig as claimed in claim 1, wherein the predetermined distance is smaller than at least 50 μm.

10. A jig as claimed in claim 1, wherein the probe pins are arranged in a grid shape.

11. A jig as claimed in claim 1, wherein the base part has a plurality of insertion holes, into which the respective probe pins are inserted, and wherein each of the probe pins has a diameter becoming smaller gradually toward the top end, and each of the insertion holes has a diameter becoming smaller gradually toward a lower portion.

12. A printed substrate inspection apparatus for inspecting a printed substrate in which wiring parts are formed on both surfaces and the wiring parts of the both surfaces are electrically connected to each other, said apparatus comprising:
a first jig for printed substrate inspection which has a configuration as claimed in claim 1 and is arranged as opposed to the one surface of the printed substrate;
a second jig for printed substrate inspection which is arranged as opposed to the other surface of the printed substrate and has a plurality of probes to be abutted on the wiring part formed on the other surface of the printed substrate; and
a control part which is connected to each of the probe pins of the first jig and each of the probes of the second jig through electrical wiring and controls a short-circuit check and a continuity check performed between each of the probe pins and each of the probes.

13. A printed substrate inspection apparatus as claimed in claim 12, wherein the second jig has a configuration as claimed in claim 1.
